(19) United States
(12) Patent Application Publication
(10) Pub. No.: US 2020/0227637 A1
(43) Pub. Date: Jul. 16, 2020

(54) DEPOSITION APPARATUS, VACUUM SYSTEM, AND METHOD OF OPERATING A DEPOSITION APPARATUS

(71) Applicant: Applied Materials, Inc., Santa Clara, CA (US)

(72) Inventors: Sebastian Gunther ZANG, Mainaschaff (DE); Andreas SAUER, Großostheim (DE); Oliver HEIMEL, Wabern (DE)

(73) Assignee: Applied Materials, Inc., Santa Clara, CA (US)

(21) Appl. No.: 15/756,550

(22) PCT Filed: Mar. 17, 2017
(86) PCT No.: PCT/EP2017/056382

§ 371 Date: Feb. 28, 2018

(51) Int. Cl. H01L 51/00; C23C 14/24; C23C 14/56; H01L 51/56

(52) U.S. Cl. CPC H01L 51/001; H01L 51/56; C23C 14/56; C23C 14/24

(57) ABSTRACT

The present disclosure provides a deposition apparatus for a vacuum deposition process. The deposition apparatus includes a vacuum chamber, a movable deposition source arranged in the vacuum chamber, and a supply arrangement providing a supply passage for media supply lines for the movable deposition source, wherein the supply arrangement comprises an axially deflectable element.

### FIELD

Embodiments of the present disclosure relate to deposition apparatuses for depositing one or more layers, particularly layers including organic materials therein, on a substrate. In particular, embodiments of the present disclosure relate to a material deposition apparatus for depositing evaporated material on a substrate in a vacuum chamber. Embodiments further relate to vacuum deposition systems and methods of operating a deposition apparatus, particularly for OLED manufacturing.

### BACKGROUND

Organic deposition apparatuses are a tool for the production of organic light-emitting diodes (OLED). OLEDs are a special type of light-emitting diode in which the emissive layer comprises a thin-film of certain organic compounds. Organic light emitting diodes (OLEDs) are used in the manufacture of television screens, computer monitors, mobile phones, other hand-held devices, etc., for displaying information. OLEDs can also be used for general space illumination. The range of colors, brightness, and viewing angles possible with OLED displays is greater than that of traditional LCD displays because OLED pixels directly emit light and do not involve a back light. Therefore, the energy consumption of OLED displays is considerably less than that of traditional LCD displays.

The manufacture of OLED devices typically involves a deposition source for coating a substrate. The deposition source is typically moved with respect to the substrate while evaporated material may be directed toward the substrate.

Deposition sources are typically supplied with supply media during operation. However, supplying a deposition source supply media may be challenging, when the deposition source moves along a source transportation path during deposition. For example, media supply lines may get damaged due to the movement of the source and there may be a risk of an interruption of the media supply. An interrupted or damaged media supply may lead to downtime of the system.

Accordingly, it would be beneficial to reduce the risk of interruptions of a deposition process and downtime of a deposition apparatus. In particular, it would be beneficial to provide a deposition apparatus with a deposition source that is reliably supplied with supply media.

### SUMMARY

In light of the above, a deposition apparatus, a vacuum system, and a method of operating a deposition apparatus are provided. Further aspects, benefits, and features of the present disclosure are apparent from the claims, the description, and the accompanying drawings.

According to one aspect of the present disclosure, a deposition apparatus for a vacuum deposition process is provided. The deposition apparatus includes a vacuum chamber; a movable deposition source arranged in the vacuum chamber; and a supply arrangement providing a supply passage for media supply lines for the movable deposition source, wherein the supply arrangement comprises an axially deflectable element.

According to another aspect of the present disclosure, a vacuum system is provided. The vacuum system includes a deposition apparatus according to any of the embodiments described herein; and a second vacuum chamber arranged adjacent to the vacuum chamber of the deposition apparatus, wherein the supply arrangement of the deposition apparatus extends at least partially out of the vacuum chamber to a space next to the second vacuum chamber.

According to a further aspect of the present disclosure, a method of operating a deposition apparatus is provided. The method includes moving a movable deposition source in a vacuum chamber; and supplying the movable deposition source via media supply lines extending through a supply passage of a supply arrangement, wherein the supply arrangement comprises an axially deflectable element.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIGS. 1a and 1b schematically show a cross-sectional view of a deposition apparatus according to embodiments described herein;

FIG. 2 schematically shows a cross-sectional view of a deposition apparatus according to embodiments described herein;

FIG. 3 schematically shows a cross-sectional view of a deposition apparatus according to embodiments described herein;

FIG. 4 schematically shows a top view of a vacuum system according to embodiments described herein;

FIG. 5 schematically shows a side view of a vacuum system according to embodiments described herein; and

FIG. 6 shows a chart illustrating a method of operating a deposition apparatus according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

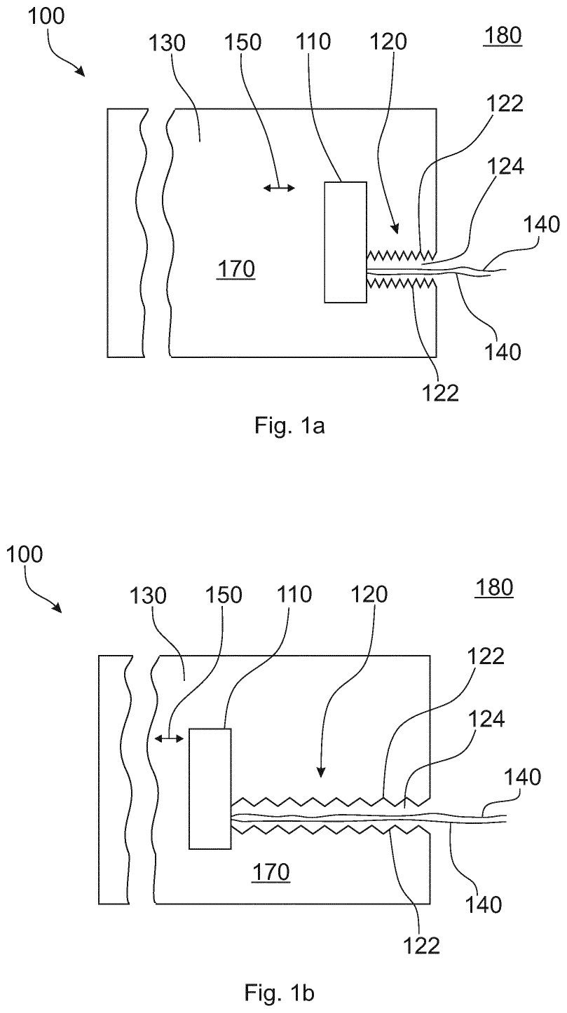

FIG. 1a and FIG. 1b show a schematic cross-sectional view of a deposition apparatus 100 for a vacuum deposition process.

The deposition apparatus 100 includes a vacuum chamber 130. In particular, the vacuum chamber 130 is configured for vacuum deposition and can be, for example, a coating chamber or a processing chamber. The term “vacuum”, as used herein, can be understood in the sense of a technical vacuum having a vacuum pressure of less than, for example, 10 mbar. As exemplarily shown in FIG. 1a and FIG. 1b, the deposition apparatus 100 includes a movable deposition source 110. The movable deposition source 110 may be a device or assembly configured for providing a source of material to be deposited on a substrate. In particular, the movable deposition source 110 may be an evaporation source configured to direct an evaporated material toward the substrate. For example, the movable deposition source 110 may be configured for coating a substrate with organic material. For the purposes of the present disclosure, the movable deposition source 110 may also be understood as a movable consumer which consumes supply media which are supplied to the moveable deposition source.

Deposition apparatuses according to embodiments described herein may be used for display manufacture on large area substrates. Large area substrates or carriers supporting a large area substrate, i.e. large area carriers, may have a size of at least 0.174 m². Typically, the size of the carrier can be about 1.4 m² to about 8 m², more typically about 2 m² to about 9 m² or even up to 12 m².

As exemplarily shown in FIG. 1a and FIG. 1b, a movable deposition source 110 may be arranged inside the vacuum chamber 130 of the deposition apparatus 100. The vacuum chamber 130 is adapted to maintain a vacuum inside the vacuum chamber volume 170. An atmospheric environment 180, for example, an atmospheric environment with an atmospheric pressure of about 1 bar, may surround the vacuum chamber. The movable deposition source 110 may be movable in a first direction 150 in the vacuum chamber 130. For example, the movable deposition source 110 may be movable along tracks provided in the vacuum chamber 130. In some embodiments, the movable deposition source 110 may be movable along a linear path, i.e. the source movement may be a straight translational movement.

In FIG. 1a, the movable deposition source 110 is at a first position. The movable deposition source 110 may be movable along a source transportation path in the vacuum chamber 130, e.g. in a deposition chamber or processing chamber. Evaporated material may be directed toward one or more substrates while the movable deposition source 110 moves along the source transportation path, e.g. between the first position and a second position. Accordingly, the source transportation path may extend between the first position and the second position.

In some embodiments, the source transportation path may have a length, for example, the distance between the first position and the second position, of 0.5 m or more, particularly 1 m or more, more particularly about 2 m. The length of the transportation path may be less than 10 m, for example, less than 8 m, less than 5 or less than 3 m. The substrate may be stationary during the deposition by the movable deposition source 110. For example, the deposition of material on a stationary substrate with a moving deposition source may be favorable for, but not limited to, large area substrates.

In FIG. 1b, the movable deposition source 110 has moved from the first position, exemplarily shown in FIG. 1a, to the second position in the vacuum chamber 130. In some embodiments, the movement of the movable deposition source 110 is a continuous movement or a step-wise movement from the first position to the second position along a source transportation path. During the source movement, evaporated material may be deposited on a substrate that is arranged in a deposition area in the vacuum chamber 130.

In some embodiments, a source drive for moving the movable deposition source along the source transportation path may be provided. The source drive may include a driving unit configured for moving the movable deposition source along tracks in a vacuum chamber. In some embodiments, a holding device such as a magnetic levitation device may be provided for carrying at least a part of the weight of the movable deposition source during the movement of the movable deposition source. The driving force to be generated by the source drive may be reduced and particle generation due to friction can be decreased.

According to embodiments described herein, the deposition apparatus 100 includes a supply arrangement 120, as shown in FIG. 1a and FIG. 1b. The supply arrangement 120 may be configured as a feed-through for guiding media supply lines 140 from an environment of the vacuum chamber 130 to the movable deposition source 110 through a wall of the vacuum chamber. The supply arrangement 120 provides a supply passage 124 for the media supply lines 140 for the movable deposition source 110. For example, the supply arrangement 120 forms a supply passage 124 for media supply lines 140 that supply the deposition source with supply media such as electricity, cooling fluids and/or signals.

The supply passage 124 may be a tubular supply passage, i.e. the supply arrangement 120 may provide a passage to the movable deposition source 110 that is surrounded by a tubular element. In particular, the supply arrangement 120 according to embodiments described herein may provide a supply passage 124 with an increased space available for media supply lines 140.

For example, the supply passage 124 may have a diameter of 50 mm or more, particularly of 100 mm or more, more particularly about 200 mm, or more. In some embodiments, the cross-sectional area of the supply passage 124 for arranging the media supply lines is 50 cm², in particular 100 cm² or more, more particularly 300 cm² or more.

In particular, a first end of the supply arrangement 120 can be coupled to the movable deposition source 110. The supply passage 124 of the supply arrangement 120 may extend through a wall of the vacuum chamber 130. In particular, the supply arrangement 120 may extend from the movable deposition source 110 through an opening of the vacuum chamber 130 to an atmospheric environment 180. In some embodiments, a second end of the supply arrangement 120 is coupled to a wall of the vacuum chamber 130. In other embodiments, the supply arrangement extends out of the vacuum chamber into an environment of the vacuum chamber.

In some embodiments, the movable deposition source 110 can include an enclosure, e.g. an enclosure for providing a pressure different from a pressure in a main volume of the vacuum chamber. The enclosure may be an atmospheric enclosure configured for providing an atmospheric pressure in an inner volume thereof. The media supply lines 140 may be guided through the supply passage into an inner volume of the enclosure. Accordingly, the enclosure may be adapted to maintain an atmospheric environment, such as an atmospheric pressure of about 1 bar. In some embodiments, the supply passage 124 may connect the enclosure to the atmospheric pressure provided outside of the vacuum chamber 130. Accordingly, the supply passage 124 can provide a fluid connection of the enclosure with the environment outside of the vacuum chamber 130.

According to embodiments described herein, the supply arrangement 120 includes an axially deflectable element 122. The term “axially deflectable” element can be understood as an element that is deflectable, i.e. expandable and/or contractible, along a longitudinal axis of the axially deflectable element. As exemplarily shown in FIG. 1a and FIG. 1b, the deflectable element 122 may be deflectable in the first direction 150. The axial dimension of the axially deflectable element 122 may change in accordance with a displacement of the movable deposition source 110. Particularly, the deflectable element 122 may be deflectable in the movement direction of the movable deposition source 110. In other words, when the movable deposition source 110 moves, the axially deflectable element 122 may expand or contract in accordance with the movement of the movable deposition source 110.

As shown in FIG. 1a and FIG. 1b, the media supply lines 140 can be passed through the supply passage 124 to the movable deposition source 110. The supply passage 124 for the media supply lines 140 may adapt to the position of the source so that a reliable supply arrangement can be provided. For example, but not limited to, one or more power cables, one or more communication cables, one or more cooling water supply lines, supply lines for providing a coolant to the deposition source and/or current supply lines for supplying the deposition source with power may extend along the supply passage through the supply arrangement. Further, as the axially deflectable element 122 may extend and deflect in the axial direction, the supply arrangement 120 according to embodiments described herein may be particularly space-saving.

In particular, as compared to supply arrangements which use an articulated arm with one or more joints providing curved portions, the supply arrangement 120 according to embodiments described herein may be particularly maintenance-friendly and space-saving. For example, the axially deflectable element 122 may extend in a linear direction, i.e. without joints or other bended portions. Space requirements can be reduced and a less complex, maintenance-friendly supply arrangement can be provided. Further, the mass and thus the tare weight of the supply arrangement may be reduced by a supply arrangement that includes an axially deflectable element. Supply arrangements with jointed or articulated levers may use a folding movement when supplying a moving source. The tare weight of a lever connected to the moving source may apply a force in the horizontal direction onto the deposition source. A device for compensating said force may be used. In contrast, providing a supply arrangement with a deflectable element as described herein may be beneficial because a scale-up of the deposition apparatus may be easily possible. This may further reduce the cost of ownership.

In FIG. 1a, the movable deposition source 110 is at a first position. When the movable deposition source 110 is at the first position, the axially deflectable element 122 may be in a contracted state. The contracted state may be a state in which the deflectable element 122 has a smaller length compared to an expanded state. In FIG. 1b, the movable deposition source 110 is at a second position in which the axially deflectable element is in the expanded state.

The supply arrangement 120 can be coupled to the movable deposition source 110. In particular, an end portion of the deflectable element 122 may be coupled to the movable deposition source 110. Accordingly, in FIG. 1b, the deflectable element 122 is in the expanded state having a larger length compared to the contracted state. The deflectable element 122 has expanded by adapting to the movement of the movable deposition source 110. Correspondingly, if the movable deposition source 110 moves from a first position to a second position, the axially deflectable element 122 has contracted by adapting to the movement of the movable deposition source 110. Accordingly, a dimension, i.e. the length, of the deflectable element 122 has adapted. For example, a length difference of the deflectable element between an expanded state and a contracted state may be 0.5 m or more, more particularly 1 m or more, or even about 2 m or more.

According to some embodiments, which can be combined with embodiments described herein, an axis of the axially deflectable element 122, for example, the longitudinal axis, may extend in the first direction 150. The media supply lines 140 can be guided through the supply passage 124 during the movement of the movable deposition source 110 which may reduce the risk of kinks, bends, or breakages of the media supply lines 140.

According to some embodiments, which can be combined with embodiments described herein, the axially deflectable element 122 can be an expansion joint. The expansion joint can expand and/or contract according to an outer force applied on the expansion joint, such as an axial force or movement. In some embodiments, the expansion joint can be an expansion joint including metal. The metal expansion joint may be a flexible metal tube. For example, the metal expansion joint may have a gas-tight wall for maintaining a first pressure in an inner volume and a second pressure in a surrounding volume.

According to some embodiments, which can be combined with embodiments described herein, the deflectable element 122 can be a bellow. The bellow may be made of a gas-tight material so that an interior of the bellow may be sealed off from an exterior of the bellow by the wall of the bellow. A first pressure in the inner volume of the bellow may be, therefore, different from a second pressure in the main volume of the vacuum chamber 130. The bellow can be an elastic element or vessel that can expand and/or contract when an outer force is applied thereon. The bellow may be a bellow that returns to an initial state when the outer force is no longer applied. In some embodiments, the below may be made of metal or metal alloys.

According to some embodiments, which can be combined with embodiments described herein, the deflectable element 122 may be an edge welded bellow. Edge welded bellows may be, for example, made by welding together individual metal diaphragms.

The bellow can be, for example, a linear bellow that is linearly deflectable, such that the bellow extends or contracts linearly. Bellows can securely seal vacuum to atmosphere and are able to withstand cycle demands. Bellows can be readily provided for a plurality of source transportation path lengths. This can, for example, reduce the cost of ownership. Further a deposition apparatus may be provided for large source transportation path lengths, for example, for a deposition process for large area substrates.

According to embodiments, which can be combined with embodiments described herein, the axially deflectable element 122 may extend along an axis in a first direction, and the dimension of the axially deflectable element 122 in the first direction 150 can be changed by expanding and/or compressing the axially deflectable element 122 along the axis, e.g. by applying an expansion force or a compression force to the axially deflectable element 122. For example, the axially deflectable element 122 may be a flexible element or an elastic element. In some embodiments, the axially deflectable element 122 is an axially bendable element. In some embodiments, the axially deflectable element 122 can also be deflected in a sideway direction, e.g. bended or curved.

Typically, the axially deflectable element 122 is configured to be sealingly coupled to a wall of the vacuum chamber 130 and/or sealingly coupled to the movable deposition source 110. Accordingly, the media supply lines 140 can be provided inside the supply passage 124.

According to embodiments, which can be combined with other embodiments described herein, the supply arrangement 120 can be configured for feeding the media supply lines 140 from an environment outside the vacuum chamber along the supply passage 124 to an enclosure, in particular an atmospheric casing, of the movable deposition source. The atmospheric casing may be configured to maintain atmospheric pressure when disposed inside the vacuum chamber. The atmospheric casing, which can also be described as an atmospheric housing or an atmospheric box, may house elements for operating the movable deposition source. For example, at least one element selected from the group consisting of: a switch, a valve, a controller, a cooling unit and a cooling control unit can be provided inside the atmospheric casing. The cooling unit typically cools the movable deposition source 110 during operation by providing a cooling fluid, such as water. A controlling unit may control the temperature of the cooling fluid and/or may control the temperature of the movable deposition source 110. Further, one or more controllers may be disposed in the atmospheric housing for controlling control parameters of the deposition process. In light thereof, the supply passage 124 may provide an increased space for media supply lines 140, as the supply arrangement 120 can be easily scaled to an applicable size, i.e. by the selection of the diameter of the deflectable element.

In FIGS. 1a and 1b, an inner volume of the axially deflectable element is in fluid connection with the atmospheric environment 180. The term “fluid connection” as used herein, can be understood as a fluid flow or exchange between two volumes. For example, a change of one parameter in one volume, such as pressure, can induce a corresponding change in the other volume.

The term “substrate” as used herein may particularly embrace substantially inflexible substrates, e.g., a wafer, slices of transparent crystal such as sapphire or the like, or a glass plate. However, the present disclosure is not limited thereto and the term “substrate” may also embrace flexible substrates such as a web or a foil. For instance, the substrate may be made of a material selected from the group consisting of glass (for instance soda-lime glass, borosilicate glass etc.), metal, polymer, ceramic, compound materials, carbon fiber materials or any other material or combination of materials which can be coated by a deposition process.

The movable deposition source, according to embodiments described herein, may include a crucible configured to evaporate the material to be deposited and a distribution assembly configured for directing the evaporated material toward the substrate. For example an organic material for depositing a thin film may be guided from the crucible via the distribution assembly through one or more outlets of the distribution assembly toward the substrate. The distribution assembly may include a distribution pipe.

According to some embodiments, which can be combined with embodiments described herein, the media supply lines may extend from the movable deposition source through the supply passage 124. The media supply lines 140 may comprise at least one or more of: a cooling channel, an electrical connection, a cable for supplying the movable deposition source with power, a cable for supplying the movable deposition source with signals, a cable for guiding sensor signals, a gas channel, a water channel.

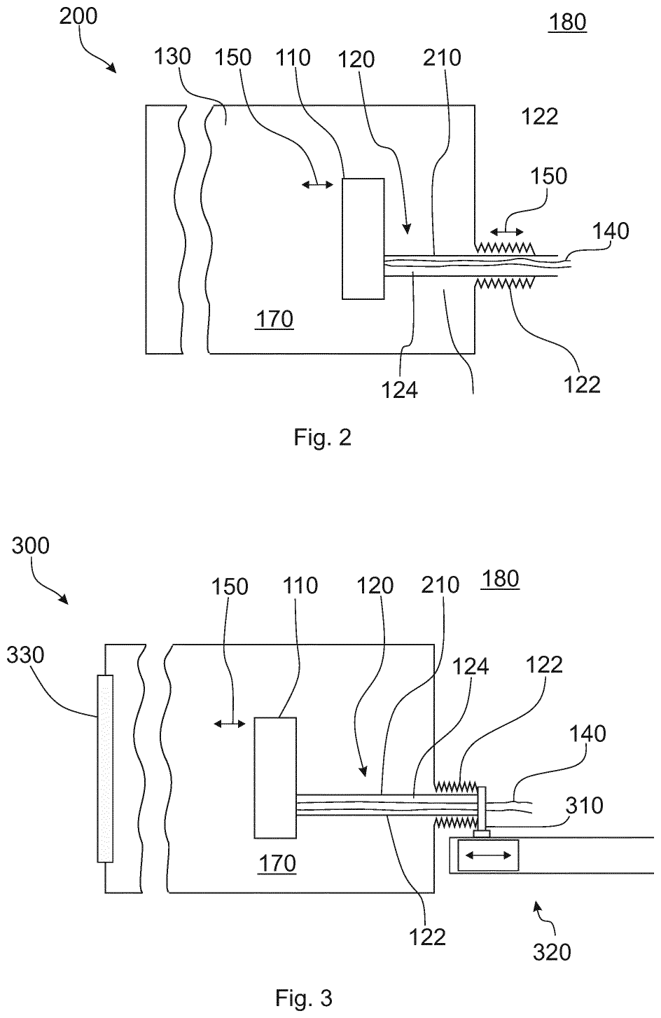

FIG. 2 schematically shows a deposition apparatus 200 according to embodiments described herein. The deposition apparatus 200 of FIG. 2 may include some or all of the features of the deposition apparatus 100 of FIG. 1 so that reference can be made to above explanations which are not repeated here.

In particular, the deposition apparatus 200 includes a movable deposition source 110 arranged in the vacuum chamber and a supply arrangement 120 configured for supplying the movable deposition source 110 with supply media.

The supply arrangement 120 of the deposition apparatus 200 includes an axially deflectable element 122 and a stiff tube element 210 which provides the supply passage 124 for the media supply lines 140.

In some embodiments, the supply arrangement 120 may include a tube element. The tube element may be, for example, an element having a tubular form, such as a cylindrical tube or a rectangular tube. An inner volume of the tube element may be surrounded by a tube wall. In some embodiments, the tube element is a stiff tube element 210 as exemplarily shown in FIG. 2. The stiff tube element 210 may be made of a stiff material. As exemplarily shown in FIG. 2, the stiff tube element may be an element that provides the supply passage 124, e.g. for the supply lines in an inner volume thereof. The stiff tube element 210 may provide an inner volume forming the supply passage 124. In FIG. 2, the stiff tube element 210 is a linear tube, e.g. a linear tube made of metal. The stiff tube element may be made of other materials, particularly gas-tight materials, in other embodiments. The material of the stiff tube element may be configured to maintain an atmospheric environment in an inner volume of the stiff tube element, while being surrounded by an environment at a subatmospheric pressure.

A first end of the stiff tube element 210 may be sealingly coupled to the movable deposition source 110, as is schematically depicted in FIG. 2. The sealing may be configured to seal off a vacuum environment which may surround the stiff tube element from an atmospheric environment provided inside the stiff tube element 210. The stiff tube element 210 may extend from the movable deposition source towards an opening of the vacuum chamber 130 and may protrude through the opening out of the vacuum chamber.

According to some embodiments, which can be combined with embodiments described herein, the stiff tube element 210 may linearly extend in the first direction 150 through an opening in a wall of the vacuum chamber. A stiff tube element may be a non-flexible element, i.e. an element that is not contractible or extendable upon application of a force, e.g. in the first direction. For example, the stiff tube element can be a hollow metal tube providing suitable rigidness.

According to embodiments, which can be combined with other embodiments described herein, a first end of the axially deflectable element 122 may be sealingly connected to a portion of the stiff tube element 210 protruding out of the vacuum chamber 130. A second end of the axially deflectable element 122 may be sealingly connected to a wall of the vacuum chamber 130. As is shown in FIG. 2, the first end of the axially deflectable element 122 may be coupled to the wall of the vacuum chamber 130 by a first coupling portion. The second end of the axially deflectable element 122 may be coupled to the stiff tube element 210 by a second coupling portion. The first and the second coupling portions can seal off the vacuum chamber 130 to maintain the vacuum provided therein.

Using the axially deflectable element as a sealing element between the vacuum chamber and a portion of the stiff tube element protruding out of the vacuum chamber may be beneficial, since particle generation in a main volume of the vacuum chamber can be reduced and the deposition result can be improved.

The stiff tube element 210 can be movable together with the movable deposition source 110. Due to the coupling of the movable deposition source 110 and the stiff tube element 210, a linear translation of the movable deposition source 110 may be accompanied by a linear translation of the stiff tube element 210. The stiff tube element 210 may be movable together with the movable deposition source 110, for example, in the first direction 150. Accordingly, due to the coupling of the stiff tube element 210 to the axially deflectable element 122, the axially deflectable element 122 adapts to the linear translation of the stiff tube element 210. For instance, by linearly translating the movable deposition source 110 in the first direction 150, the stiff tube element 210 follows the linear translation in the first direction 150. Accordingly, the axially deflectable element 122 can compress during the translation in the first direction 150. Similarly, the axially deflectable element may expand during a translation of the movable deposition source in an opposite direction.

According to some embodiments, which can be combined with embodiments described herein, the axially deflectable element 122 may surround the stiff tube element 210. In particular, at least a section of the stiff tube element may be enclosed by the axially deflectable element 122. The inner volume of the stiff tube element 210 can be in fluid connection with an atmospheric environment 180. A circumferential volume between the stiff tube element 210 and the axially deflectable element 122 can be in fluid connection with a main volume of the vacuum chamber 130. Accordingly, an inner volume of the stiff tube element 210 which is connected to the movable deposition source 110 may be in fluid connection with the atmospheric casing of the movable deposition source 110.

FIG. 3 shows a deposition apparatus 300 according to embodiments described herein. The deposition apparatus 300 shown in FIG. 3 may include some features or all features of the deposition apparatus 200 shown in FIG. 2 so that reference can be made to the above explanations which are not repeated here.

In particular, the deposition apparatus 300 includes the movable deposition source 110 and the supply arrangement 120 which provides the supply passage 124 for supplying media supply lines from on atmospheric environment of the vacuum chamber 130 to the deposition source. The supply arrangement 120 may be similar to the supply arrangement depicted in FIG. 2 so that reference can be made to the above explanations. In particular, the supply arrangement 120 may include the stiff tube element 210 which forms the supply passage for the media supply lines and the axially deflectable element 122 which partially surrounds the stiff tube element 210.

In particular, the axially deflectable element 122 may include a bellow or another expansion joint with a first end connected to an end of the stiff tube element protruding out of the vacuum chamber and a second end connected to a wall of the vacuum chamber. In particular, the second end of the axially deflectable element may be connected to an edge of an opening provided in the wall of the vacuum chamber.

According to some embodiments, which can be combined with embodiments described herein, the deposition apparatus 100 may include a drive unit 320 for moving the movable deposition source 110, as exemplarily shown in FIG. 3. The drive unit 320 may be configured to move the movable deposition source along the source transportation path, particularly in a linear direction corresponding to the first direction 150. In some embodiments, the driving unit 320 is connected to or part of the supply arrangement. In particular, the drive unit 320 may be coupled to a portion of the supply arrangement 120. The supply arrangement 120 and the movable deposition source 110 may then be translated or moved together by the drive unit 320.

In some embodiments, the drive unit 320 may be arranged outside of the vacuum chamber 130, particularly coupled to a portion of the supply arrangement which protrudes out of the vacuum chamber. The drive unit 320 may be operated under atmospheric conditions which may allow for the use of a regular drive unit. For example, the drive unit 320 may include a motor such as a linear motor configured for moving the stiff tube element. In particular, a wear-resistant and low-maintenance drive unit may be provided outside the vacuum chamber for moving the deposition source. Moreover, a drive unit 320 arranged outside of the vacuum chamber 130 can be supplied with power and control signals more easily. The drive unit 320 can be easily accessible. The supply arrangement 120 may offer more space for supply lines and the supply arrangement 120 may be reduced in size.

In some embodiments, which can be combined with embodiments described herein, the drive unit 320 may be coupled to a portion 310 of the stiff tube element 210 protruding out of the vacuum chamber. For example, the stiff tube element 210 may include a driven portion or a guided portion which is driven by the drive unit. For example, the driven portion may be situated at a first end of the stiff tube element 210, as is shown in FIG. 3. The stiff tube element 210 may convey the translation provided by the drive unit 320 to the movable deposition source 110.

In some embodiments, which can be combined with embodiments described herein, the stiff tube element 210 can be configured as a translation element configured for translating a driving force of the drive unit 320 to the movable deposition source 110. For example, the stiff tube element 210 may be moved by a motor such as a linear motor that may be arranged outside the vacuum chamber.

In some embodiments, the deposition apparatus 100 may include a servicing area or maintenance area, wherein a closable passage 330 may be provided between the vacuum chamber and the servicing area, as is exemplarily depicted in FIG. 3. The closable passage 330 can be opened to move the deposition source between the vacuum chamber and the servicing area. The deposition source can be transferred into the servicing area, e.g., for service or maintenance.

According to embodiments described herein, the media supply lines for supplying the deposition source may be guided out of the vacuum system via the supply passage, and not via the servicing area which is connected to the vacuum chamber with the closable passage 330. Accordingly, a servicing area with a reduced space may be provided. In some embodiments, it may even be possible to provide a deposition apparatus including a vacuum chamber, wherein no servicing area for servicing the deposition source may be provided as a separable compartment of the vacuum system next to the vacuum chamber. In particular, the media supply lines may be directly fed from the deposition source through the supply passage to an atmospheric environment of the vacuum system. An outer dimension of the deposition apparatus may be reduced, when a smaller servicing area or no servicing area at all may be needed as a separate compartment next to the deposition chamber. Further, no closable passage 330 between the vacuum chamber and a servicing area may be provided.

In some embodiments, the vacuum chamber may include a passage, e.g. a servicing door, optionally with a valve, for opening and closing the vacuum chamber for accessing and servicing the movable deposition source. For example, the servicing door may be used for at least one of exchanging a part of the deposition source, service or maintenance of any of the devices of the deposition source which are supplied by the media supply lines, repairing the deposition source, and/or accessing a part of the media supply lines which are not easily accessible via the supply passage from an outside of the evacuated chamber.

According to another aspect of the present disclosure, a vacuum system is provided.

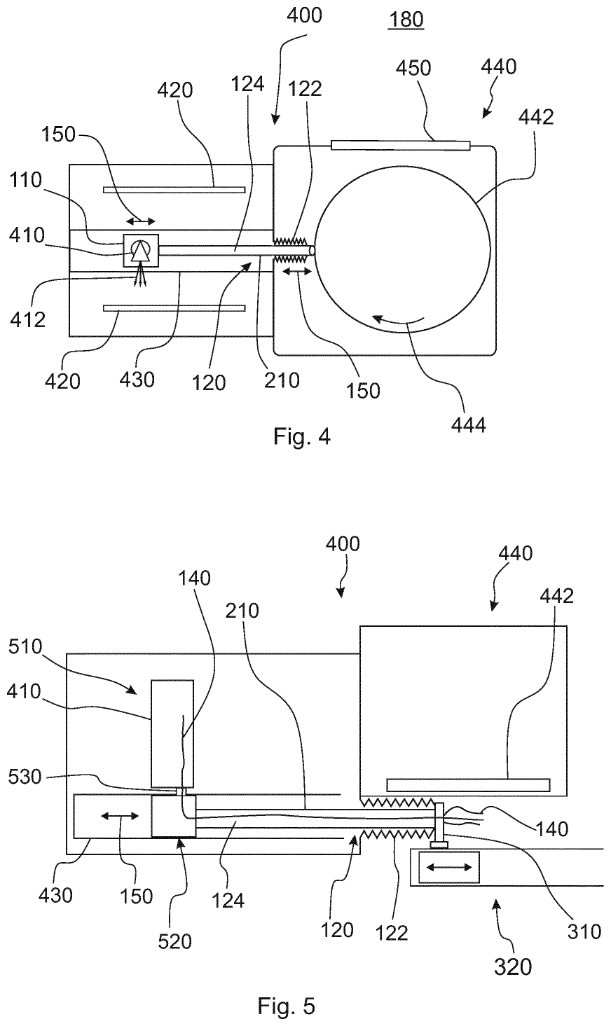

FIG. 4 shows a vacuum system 400 including a deposition apparatus according to any of the embodiments described herein. The deposition apparatus includes a vacuum chamber 130 and a movable deposition source arranged in the vacuum chamber 130. The vacuum system 400 may further include a second vacuum chamber 440. The second vacuum chamber 440 can be arranged adjacent to the vacuum chamber 130. A passage for moving one or more substrate between the vacuum chamber and the second vacuum chamber 440 may be provided. In particular, substrates to be coated may be transferred from the second vacuum chamber into the vacuum chamber through a passage, and coated substrates may be transferred from the vacuum chamber to the second vacuum chamber. The second vacuum chamber may be, e.g. a transit chamber, a routing module or a rotation module.

In FIG. 4, the movable deposition source 110 includes a distribution pipe 410 which may be rotatable. The distribution pipe 410 may extend along a length direction, particularly in an essentially vertical direction. The distribution pipe 410 may have one or more outlets to spray evaporated material 412 on a substrate 420. A surface of the substrate 420 may extend in the first direction, which is, for example, a direction of the source transportation path.

FIG. 4 shows two substrates which may be arranged opposite to each other. In particular, the source transportation path may extend in an area between the two substrates. In some embodiments, a mask for masking the layer deposition on a substrate can be provided between the substrate and the movable deposition source 110, for example in close proximity of the substrate. The distribution pipe 410 can be rotated, for example, rotated by about 180° from a first deposition area where a first substrate may be arranged to a second deposition area where a second substrate may be arranged.

When the movable deposition source 110 is linearly moved in the first direction 150, the stiff tube element 210 may also move linearly in the first direction, as the stiff tube element is connected to the movable deposition source 110. The linear movement of the movable deposition source 110 may be guided by a transportation track 430 which may extend in the first direction. Accordingly, the media supply lines 140 disposed in the supply passage 124 of the stiff tube element 210 can supply the movable deposition source 110 when it is moved. The axially deflectable element 122 may be deflected during a movement of the movable deposition source 110. Further, the axially deflectable element may provide a sealing between a main volume of the vacuum chamber and an environment of the vacuum chamber 130.

The second vacuum chamber 440 of the vacuum system 400 may include a rotating device 442. In particular, the second vacuum chamber 440 can be a rotation module. The rotating device 442 may be configured to receive one or more substrates. The rotating device 442 may be configured to change the orientation of the one or more substrates from a first orientation to a second orientation. For example, the orientation can be changed by rotating the substrate 420, figuratively illustrated by reference numeral 444. Changing the orientation can be useful, when a third vacuum chamber is not aligned with the second vacuum chamber 440, such as, for example, a third vacuum chamber connected to a gate valve 450. The substrate 420 can be then rotated by about 90° to transfer the substrate to the third vacuum chamber.

In some embodiments, which can be combined with embodiments described herein, the supply arrangement 120 of the deposition apparatus 100 extends at least partially out of the vacuum chamber 130. For example, the supply arrangement 120, in particular, the stiff tube element 210, may protrude out of the vacuum chamber on a side of the vacuum chamber which is connected to the second vacuum chamber.

FIG. 5 shows a schematic side view of the vacuum system 400. The supply arrangement 120 extends out of the vacuum chamber 130 to a space next to, particularly below, the second vacuum chamber 440. In particular, the space below the second vacuum chamber 440 can be a space in an atmospheric environment. Accordingly, the drive unit 320 may be arranged in the space below the second vacuum chamber 440.

In some embodiments, a second deposition apparatus according to any of the embodiments described herein may be arranged adjacent to the second vacuum chamber 440. In particular, the second deposition apparatus can be arranged at the opposite site of the second vacuum chamber 440 with respect to the first deposition apparatus.

The second deposition apparatus may include a second supply arrangement that may be configured according to the supply arrangement of any of the deposition apparatuses described herein. In particular, the second supply arrangement may include a stiff tube element which forms a supply passage for media supply lines for a second deposition source of the second deposition apparatus. Further, the second supply arrangement may include an axially deflectable element which may at least partially surround the stiff tube element and may be compressible and contractible along the axis of the stiff tube element. The stiff tube element of the second supply arrangement may be arranged parallel to the stiff tube element of the supply arrangement of the first deposition source, e.g. with an offset therebetween, such that the stiff tube elements do not interfere with each other when protruding out of the respective vacuum chamber. Accordingly, both the supply arrangement and the second supply arrangement may be movable in the first direction 150, particularly parallel to each other.

In some embodiments, the supply arrangement and/or the second supply arrangement may extend into the space next to, particularly below, the second vacuum chamber 440. When operating the deposition apparatus, e.g. when moving the movable deposition source and/or the second deposition source, the supply arrangements may move next to each other into the space below the second vacuum chamber 440. This arrangement may be space saving and the footprint of the vacuum system 400 may be reduced.

As is schematically depicted in FIG. 5, the movable deposition source 110 may have an upper section 510 and a lower section 520. The lower section 520 can include a source cart that may be in contact with source tracks of the source transportation path. The upper section 510 may include one or more distribution pipes, e.g. the distribution pipe 410. Any of the first section and the second section may include an atmospheric enclosure or an atmospheric casing into which at least some of the media supply lines are guided via the supply passage. The lower section 520 may be connected to the supply arrangement 120, in particular to the stiff tube element 210. Further, the lower section 520 may be in contact with the transportation track 430.

The upper section 510 may be detachably connected to the lower section 520, e.g. by a docking port 530. In some embodiments, the upper section 510 includes the distribution pipe 410. The distribution pipe may be rotatable with respect to the lower section 520. The docking port 530 can be a connecting part that couples the upper section 510 and the lower section 520. The docking port 530, which can also be described as a multi-coupling, can be utilized to remove the upper section 510 of the movable deposition source 110, for example, for maintenance, and to connect another upper section 510 to the lower section. In other words, the upper sections of the deposition source can be swapped.

According to a further aspect of the present disclosure, a method of operating a deposition apparatus 100 is provided.

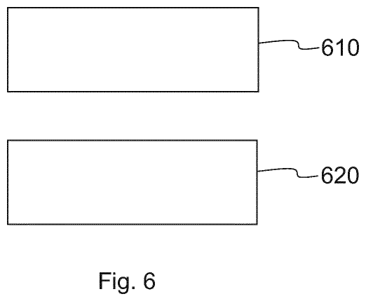

FIG. 6 is a diagram illustrating a method of operating a deposition apparatus 100. The method includes moving a movable deposition source 110 in a vacuum chamber 130 (box 610). The method further includes supplying the movable deposition source 110 with supply media via media supply lines 140. The media supply lines may extend through a supply passage 124 of a supply arrangement 120, which includes an axially deflectable element 122 (box 620). In particular, the axially deflectable element 122 may axially contract or expand in a first direction when the movable deposition source 110 linearly moves in the first direction. The supply arrangement 120 may include some features or all the features of any of the supply arrangement of any of the deposition apparatuses described herein so that reference can be made to the above embodiments.

Moving the movable deposition source 110 may further include driving the movable deposition source 110 by a drive unit coupled to a portion of the supply arrangement 120.

The drive unit may be arranged outside the vacuum chamber 130. The drive unit 320 may be coupled to a stiff tube element 210 of the supply arrangement 120 protruding outside the vacuum chamber 130.

While the foregoing is directed to embodiments of the disclosure, other and further embodiments of the disclosure may be devised without departing from the basic scope thereof, and the scope thereof is determined by the claims that follow.

1. A deposition apparatus for a vacuum deposition process, comprising:
a vacuum chamber;
a movable deposition source arranged in the vacuum chamber; and
a supply arrangement providing a supply passage for media supply lines for the movable deposition source, wherein the supply arrangement comprises an axially deflectable element.

2. The deposition apparatus according to claim 1, wherein the axially deflectable element is an expansion joint, particularly a bellow, more particularly an edge welded bellow.

3. The deposition apparatus according to claim 1, wherein the movable deposition source is linearly movable in a first direction, and wherein an axis of the axially deflectable element extends in the first direction.

4. The deposition apparatus according to claim 1, wherein the supply arrangement is configured for passing the media supply lines from an environment outside the vacuum chamber along the supply passage to an atmospheric casing of the movable deposition source.

5. The deposition apparatus according to claim 1, further comprising the media supply lines extending from the movable deposition source through the supply passage, wherein the media supply lines comprise at least one or more of: a cooling channel, an electrical connection, a cable for supplying the movable deposition source with power, a cable for supplying the movable deposition source with signals, a cable for guiding sensor signals, a gas channel, and a water channel.

6. The deposition apparatus according to claim 1, wherein the supply arrangement further comprises a stiff tube element, and wherein an inner volume of the stiff tube element forms the supply passage.

7. The deposition apparatus according to claim 6, wherein the stiff tube element linearly extends in a first direction through an opening in a wall of the vacuum chamber.

8. The deposition apparatus according to claim 7, wherein a first end of the axially deflectable element is sealingly connected to a portion of the stiff tube element protruding out of the vacuum chamber and/or wherein a second end of the axially deflectable element is sealingly connected to the wall of the vacuum chamber.

9. The deposition apparatus according to claim 6, wherein the axially deflectable element surrounds the stiff tube element, wherein the inner volume of the stiff tube element is in fluid connection with an atmospheric environment, and wherein a circumferential volume between the stiff tube element and the axially deflectable element is in fluid connection with a main volume of the vacuum chamber.

10. The deposition apparatus according to claim 1, wherein a drive unit for moving the movable deposition source is coupled to a portion of the supply arrangement, particularly to a portion of a stiff tube element protruding out of the vacuum chamber.

11. The deposition apparatus according to claim 10, wherein the stiff tube element is configured as a translation element configured for translating a driving force of the driving unit which is arranged outside the vacuum chamber to the movable deposition source.

12. A vacuum system, comprising:
a deposition apparatus for a vacuum deposition process, the deposition apparatus comprising:
a first vacuum chamber;
a movable deposition source arranged in the first vacuum chamber; and
a supply arrangement providing a supply passage for media supply lines for the movable deposition source, and wherein the supply arrangement comprises an axially deflectable element;
the vacuum system further comprising a second vacuum chamber arranged adjacent to the first vacuum chamber of the deposition apparatus, wherein the supply arrangement of the deposition apparatus extends at least partially out of the first vacuum chamber to a space next to the second vacuum chamber.

13. A method of operating a deposition apparatus, comprising:
moving a movable deposition source in a vacuum chamber; and
supplying the movable deposition source via media supply lines extending through a supply passage of a supply arrangement, wherein the supply arrangement comprises an axially deflectable element.

14. The method according to claim 13, wherein the axially deflectable element contracts or expands in a first direction when the movable deposition source linearly moves in the first direction.

15. The method according to claim 13, wherein moving the movable deposition source comprises driving the movable deposition source by a drive unit arranged outside the vacuum chamber and coupled to a portion of the supply arrangement, particularly coupled to a stiff tube element of the supply arrangement protruding outside the vacuum chamber.

16. The deposition apparatus according to claim 1, wherein the deposition apparatus is for deposition of one or more layers on a substrate and wherein the movable deposition source is movable in a first direction, and wherein an longitudinal axis of the axially deflectable element extends in the first direction.

17. The deposition apparatus according to claim 1, wherein the deposition source is movable along tracks provided in the vacuum chamber.

18. The deposition apparatus according to claim 1, wherein the deposition source includes a rotatable distribution pipe.

19. The vacuum system according to claim 15, wherein the deposition apparatus is for deposition of one or more layers on a substrate, wherein the movable deposition source is movable in a first direction, and wherein an longitudinal axis of the axially deflectable element extends in the first direction.

20. The vacuum system according to claim 15, wherein the deposition source is movable along tracks provided in the vacuum chamber.
